(19) United States
(12) Patent Application Publication
(10) Pub. No.: US 2006/0237766 A1
(43) Pub. Date: Oct. 26, 2006

(54) Semiconductor device using solid phase epitaxy and method for fabricating the same

(75) Inventor: Tae-Hang Ahn, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Kyoungki-do (KR)

(21) Appl. No.: 11/323,779

(22) Filed: Dec. 30, 2005

(30) Foreign Application Priority Data
Apr. 25, 2005 (KR) 10-2005-0034106

(51) Int. Cl. H01L 29/76

(52) U.S. Cl. 257/314

(57) ABSTRACT

A semiconductor device includes an epitaxial layer using a solid phase epitaxy (SPE) process; a first metal layer on the epitaxial layer; a nitride-based barrier metal layer on the first metal layer; a second metal layer on the barrier metal layer; and a metal silicide layer formed between the epitaxial layer and the first metal layer after a post-annealing process.

### FIELD OF THE INVENTION

The present invention relates to a method for fabricating a semiconductor device; and more particularly, to a contact plug of a semiconductor device and a method for fabricating the same.

### DESCRIPTION OF RELATED ARTS

As the scale of integration has been increasing, while the size of a semiconductor device has been decreasing, dynamic random access memory (DRAM) devices have been influenced by a gradual reduction of contact size within a cell transistor. As size reduction and high integration of semiconductor devices have occurred, there has also been an increase in a contact resistance and a decrease in an operation current due to a decrease in a contact area resulting from a decrease in the contact size. Accordingly, device degradation phenomena such as degradation in a data retention time of the semiconductor device have been generated.

In order to reduce the contact resistance and improve the operation current, a method to increase a doping concentration in a junction portion of a silicon substrate or a method to increase a concentration of phosphorus (P) doped within polysilicon contact plug may be used.

However, the above described method to increase the phosphorus concentration results in degradation of an internal pressure due to a significant out-diffusion of the dopants and the decrease of a data retention time of a device.

Furthermore, polysilicon generally used as a contact material is deposited in a batch type furnace at a temperature ranging from approximately 500° C. to approximately 600° C. and in a doping concentration of P ranging from approximately 0.1×10²⁰ atoms/cm³ to approximately 3.0×10²⁰ atoms/cm³ along with supplying silane (SiH₄) and phosphine (PH₃) gases. Thus, during depositing the polysilicon, a thin oxide layer is formed in an interface between the polysilicon and the silicon substrate due to a concentration of oxygen (O₂), i.e., a concentration of O₂ of approximately several tens ppm, existing when the polysilicon is loaded to the furnace in a nitrogen (N₂) ambient. The thin oxide layer provides a factor increasing the contact resistance of the device, and a resistance of the polysilicon itself is very high.

It may be very difficult to use the polysilicon at a contact process of a semiconductor device with a size equal to or less than approximately sub-100 nm requiring a very low contact resistance.

Accordingly, to overcome the above problems, epitaxial silicon formed in a single type chemical vapor deposition (CVD) apparatus is introduced, wherein and an example of technology forming the epitaxial silicon may comprise a selective epitaxial growth (SEG) process.

FIG. 1 is a cross-sectional view illustrating a contact structure formed through a conventional SEG process.

As shown in FIG. 1, a plurality of gate patterns formed by sequentially stacking a gate oxide layer 12, a gate electrode 13, and a gate hard mask 14 are formed on a substrate 11. Also, a plurality of gate spacers 15 are formed on sidewalls of the plurality of gate patterns and an epitaxial silicon layer 16 is formed on a surface of the substrate 11 between the gate patterns by using the SEG process.

The aforementioned SEG process is a process selectively growing an epitaxial silicon layer on the exposed substrate 11. Thus, it is possible to obtain the epitaxial silicon layer 16 with a good quality in a desirable thickness through the SEG process.

However, the SEG process uses a high temperature process performed at a temperature of approximately 850° C. and thus, the SEG process cannot be applied to a current process for fabricating a semiconductor device.

In addition to the SEG process, there is a solid phase epitaxy (SPE) process. The SPE process can carry out a deposition at a low temperature without using a hydrogen (H₂) bake treatment as being used for removing a surface native oxide layer at high temperature of approximately 850° C. Also, the SPE process with a low doping concentration can sufficiently overcome a problem of polysilicon.

FIGS. 2A and 2B are cross-sectional views illustrating a method for forming a contact by using a conventional SPE process.

As shown in FIG. 2A, a plurality of gate patterns formed by sequentially stacking a gate oxide layer 22, a gate electrode 23, and a gate hard mask 24 are formed on a substrate 21. Afterwards, a plurality of gate spacers 25 are formed on sidewalls of the gate patterns. Herein, the gate patterns and the gate spacers 25 are subjected to a self-aligned contact (SAC) etching process.

Subsequently, after the SAC process, an amorphous silicon layer 27 is formed on an exposed surface of the substrate 21 between the gate patterns.

At this time, through the SPE process, the amorphous silicon layer 27 doped with phosphorous (P) in a relatively low concentration ranging from approximately 1.0×10¹⁸ atoms/cm³ to approximately 1.0×10²¹ atoms/cm³ is deposited at a temperature ranging from approximately 400° C. to approximately 700° C. by using silane (SiH₄)/phosphine (PH₃) gases. In this case, an epitaxial silicon layer 26 has been already grown on a bottom portion in an initial deposition stage and the amorphous silicon layer 27 is deposited thereon.

As shown in FIG. 2B, a thermal process is employed at a relatively low temperature ranging from approximately 500° C. to approximately 700° C. for a predetermined period in a nitrogen (N₂) atmosphere. For instance, the thermal process can be performed at approximately 400° C. for approximately two hours, or can be performed at approximately 700° C. at 30 minutes. Herein, the thermal process is performed for a longer period at a lower temperature. Through the above thermal process, an epitaxial silicon layer 28 is re-grown from a bottom portion of the epitaxial silicon layer 26 on the substrate 21 into a top portion of the contact. This epitaxial re-growth is one characteristic of the SPE process. Accordingly, if the SPE process is used, all of the amorphous silicon layer 27 and the epitaxial silicon layer 26 can be formed in the epitaxial silicon layer 28.

Polysilicon may increase a doping concentration of P to equal to or more than approximately 1.0×10²⁰ atoms/cm³ to reduce a contact resistance. Thus, the increased doping concentration of P deteriorates a data retention time of a device. However, in case of an epitaxial silicon layer using the SEG process or the SPE process, an interface property is improved so that it is possible to maintain a low contact resistance even though P is lowly doped.

However, as semiconductor devices have been more integrated with a size equal to or less than approximately sub-100 nm, it becomes desirable to maintain a much lower contact resistance. Accordingly, the epitaxial silicon layer provides a limitation in the perspective of resistivity of the epitaxial silicon layer itself. Even though P is doped in the epitaxial silicon layer at a concentration ranging from approximately 1.0×10¹⁸ atoms/cm³ to approximately 1.0×10²¹ atoms/cm³, the epitaxial silicon layer shows a high value of the resistivity ranging from approximately 0.5 mΩ-cm to approximately 1.5 mΩ-cm, and it is very difficult to reduce the value of the resistivity up to a value below the above mentioned values of the resistivity.

A semiconductor device with a size equal to or less than approximately sub-100 nm may require a much lower contact resistance than the current contact resistance provided during conventional applications of the epitaxial silicon layer. Furthermore, it is required to sufficiently secure reliability of a device and yields of products for the semiconductor device with a size equal to or less than approximately sub-100 nm. Furthermore, the application of the epitaxial silicon layer may comprise a method wherein both a cell contact region and a peripheral circuit region could be simultaneously formed.

If the epitaxial silicon layer is used particularly in the peripheral circuit region, a thin junction could form in a source/drain region and thus, it is possible to apply an elevated source/drain (ESD) structure using the epitaxial silicon layer. In the ESD structure, the source/drain where a substrate is exposed is grown into an epitaxial silicon layer, thereby not only increasing an actual height of the source/drain but also improving a resistance property.

In practice, the epitaxial silicon layer is grown in both the cell region and the peripheral circuit region through the SEG process and thus, the ESD process can be employed.

Hence, it may be desirable to apply the epitaxial silicon layer to both the cell region and the peripheral circuit region in the high integrated semiconductor device. If a basic transistor property and a junction property are considered, a low temperature epitaxial silicon process may be required. When the SEG process is not used, it may be required to use a different epitaxial silicon layer using a low temperature process.

As described above, if the epitaxial silicon layer instead of the conventional polysilicon is applied to both the cell region and the peripheral circuit region, it is possible to not only reduce the contact resistance but also form the ESD structure.

However, since the H₂ bake treatment that is a pre-treatment is a high temperature process performed at a temperature of approximately 850° C. and a temperature required to grow the epitaxial silicon layer is high at a temperature ranging from approximately 800° C. to approximately 820° C., the SEG process performed at a high temperature seriously deteriorates a channel of a device and a junction property, thereby degrading a semiconductor device.

Although the SPE process is applied, there is a limitation in reducing the contact resistance due to the high value of the resistivity that the epitaxial silicon layer itself provides.

### SUMMARY OF THE INVENTION

The present invention relates to a semiconductor device using an epitaxial silicon layer as a contact plug and a method for fabricating the same, wherein the semiconductor device is capable of forming the epitaxial silicon layer as a contact material due to a thermal process performed at a low temperature and capable of overcoming a limitation in a contact resistance from being increased by a high value of resistivity that the epitaxial silicon layer itself provides.

In accordance with one aspect of the present invention, a semiconductor device comprises: an epitaxial layer using a solid phase epitaxy (SPE) process; a first metal layer on the epitaxial layer; a nitride-based barrier metal layer on the first metal layer; a second metal layer on the barrier metal layer; and a metal silicide layer formed between the epitaxial layer and the first metal layer after a post-annealing process.

In accordance with another aspect of the present invention, a semiconductor device comprises: a substrate provided with a cell region and a peripheral circuit region; a contact formed by stacking a first contact layer as an epitaxial layer and a second contact layer as a metal material on the cell region; and an elevated source/drain (ESD) formed by stacking a first ESD layer as an epitaxial layer and a second ESD layer as a metal material on the peripheral circuit region of the substrate.

In accordance with still another aspect of the present invention, a method for fabricating a semiconductor device comprises: forming a substrate provided with a cell region and a peripheral circuit region, thereby forming a structure provided with a contact hole on the cell region and an ESD hole on the peripheral circuit region; forming an epitaxial layer filling partial portions of the contact hole and the ESD hole by using a SPE process and forming a first contact layer and a first ESD layer made of an amorphous layer on the epitaxial layer to fill the remaining portions of the contact hole and the ESD hole; selectively removing the amorphous layer from the first contact layer and the first ESD layer; and forming a second contact layer and a second ESD layer made of a metal contact layer filling the contact hole and the ESD hole on the first contact layer and the first ESD layer made of the epitaxial layer remaining after removing the amorphous layer.

### BRIEF DESCRIPTION OF THE DRAWINGS

The above and other features of the present invention will become better understood with respect to the following description of the preferred embodiments given in conjunction with the accompanying drawings, in which:

FIG. 1 is a cross-sectional view illustrating a contact structure formed by using a conventional selective epitaxy growth (SEG) process;

FIGS. 2A and 2B are cross-sectional views illustrating a method for fabricating a contact by using a conventional solid phase epitaxy (SPE) process;

FIG. 3 is a cross-sectional view illustrating a semiconductor device structure in accordance with the present invention; and

FIGS. 4A to 4G are cross-sectional views illustrating a method for fabricating a semiconductor device in accordance with the present invention.

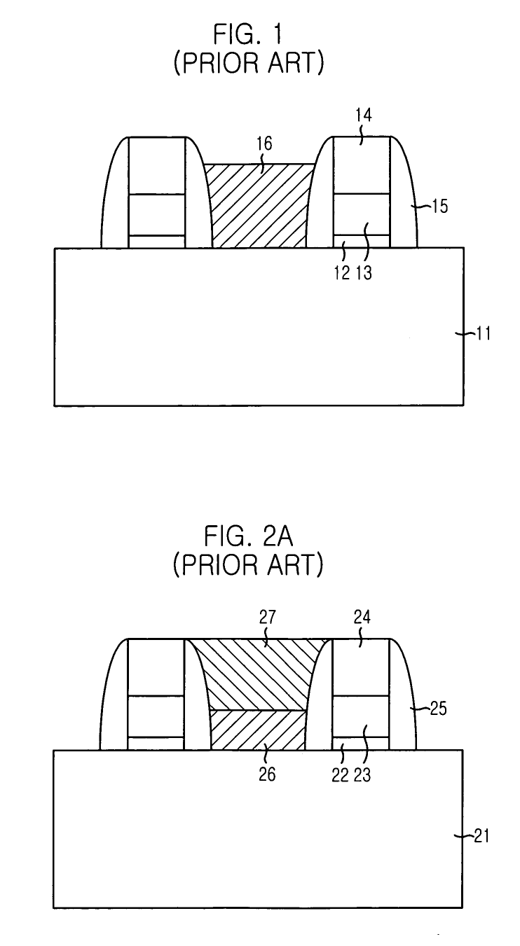

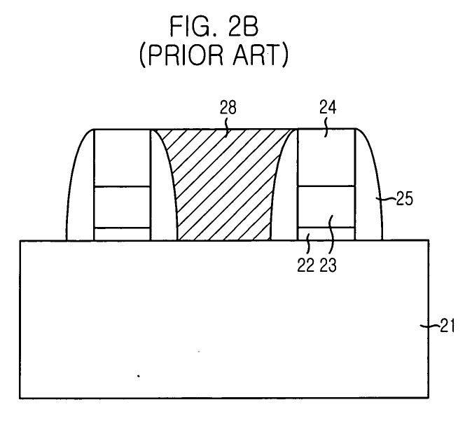

### DETAILED DESCRIPTION OF THE INVENTION

Hereinafter, detailed descriptions on embodiments of the present invention will be provided with reference to the accompanying drawings.

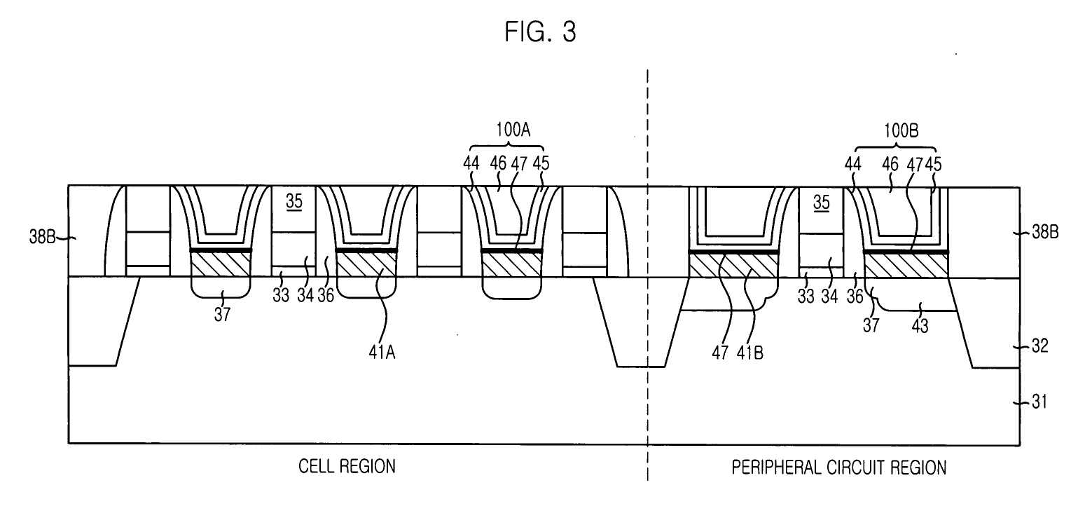

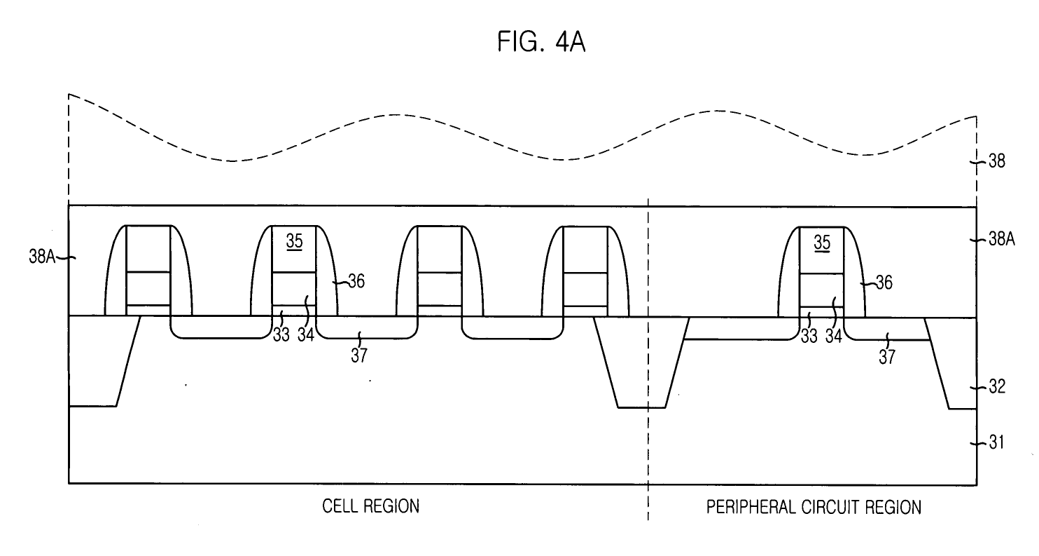

FIG. 3 is a cross-sectional view illustrating a semiconductor device structure in accordance with the present invention.

As shown in FIG. 3, the semiconductor device structure includes a substrate 31 defined with a cell region and a peripheral circuit region, a self-aligned contact (SAC) formed by sequentially stacking a first contact layer 41A that is an epitaxial layer, a second contact layer 100A that is a metal material on the cell region of the substrate 31, an elevated source/drain (ESD) formed by sequentially stacking a first ESD layer 41B that is an epitaxial layer, and a second ESD layer 100B that is a metal material on the peripheral circuit region of the substrate 31.

Referring to FIG. 3, in accordance with one embodiment of the present invention, the first contact layer 41A forming the SAC and the epitaxial layer forming the first ESD layer 41B are identical epitaxial layers, and the second contact layer 100A and the second ESD layer 100B are identical metal layers.

First, the first contact layer 41A and the first ESD layer 41B are selected from a group consisting of epitaxial silicon, epitaxial germanium, and epitaxial silicon germanium and formed through a solid phase epitaxy (SPE) process. The first contact layer 41A and the first ESD layer 41B are doped with an impurity, i.e., phosphorous (P) or arsenic (As), in a concentration ranging from approximately 1×10¹⁸ atoms/cm³ to approximately 1.0×10²¹ atoms/cm³.

The second contact layer 100A and the second ESD layer 100B comprising metal materials includes the first contact layer 41A, a first metal layer 44 on the first ESD layer 41B, a nitride-based barrier metal layer 45 on the first metal layer 44, a second metal layer 46 on the barrier metal layer 45, a metal silicide layer 47 formed between the first contact layer/the first ESD layer 41A and 41B, and the first metal layer 44. Herein, the first metal layer 44 is selected from a group consisting of titanium (Ti), cobalt (Co), and nickel (Ni). According to one embodiment of the present invention, the barrier metal layer 45 is made of either a titanium nitride (TiN) layer or a tungsten nitride (WN) layer, and the second metal layer 46 is made of tungsten (W). In accordance with an embodiment of the present invention, materials for forming the metal silicide layers 47 may comprise titanium silicide (TiSi₂), cobalt silicide (CoSi₂), and nickel silicide (NiSi₂).

The semiconductor device having the structure as shown in FIG. 3 has the SAC formed with a dual structure, i.e., the dual structure which the metal silicide layer 47 is formed, by using the first contact layer 41A/the first ESD layer 41B made of the epitaxial silicon layer formed in the SAC and the ESD, and the second contact layer 100A/the second ESD layer 100B made of the metal layer. Thus, it is possible to overcome a limitation on a contact resistance of silicon itself by forming the epitaxial silicon and the metal layer in the SAC. In accordance with an embodiment of the present invention, the present invention can provide an advantage in the perspective of the contact resistance by using the second contact layer 100A and the second ESD layer 100B made of the metal layer, wherein the resistivity of the metal layer itself is approximately 100-times lower than that of silicon.

In one embodiment of the present invention, the epitaxial silicon layer forming the first contact layer 41A and the first ESD layer 41B does not have to be subjected to a thermal process for re-growing the epitaxial silicon layer after an epitaxial silicon layer and an amorphous silicon layer is grown through a SPE process, wherein the amorphous silicon layer is selectively removed. Thus, it is possible to obtain a process simplification and reduce a thermal budget.

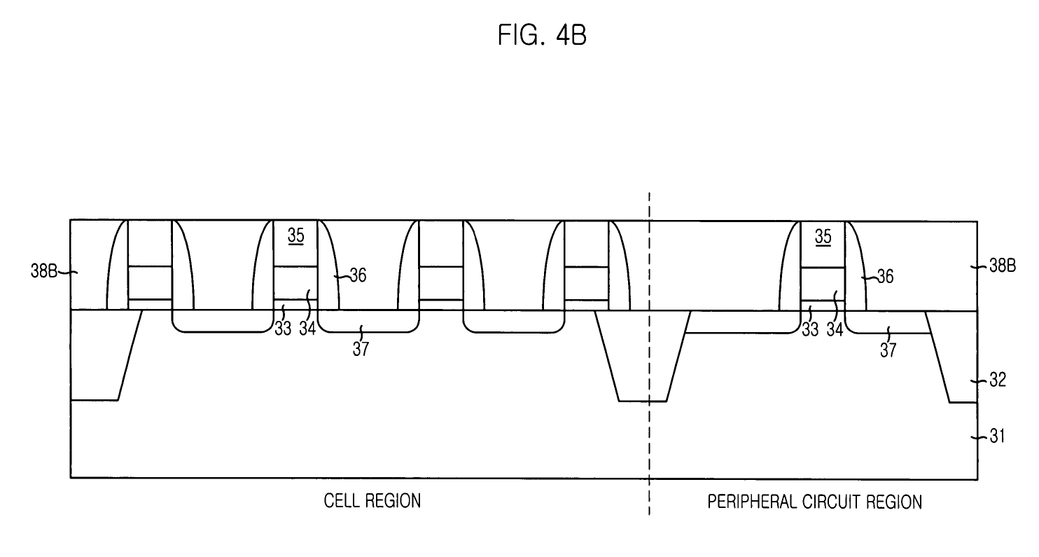

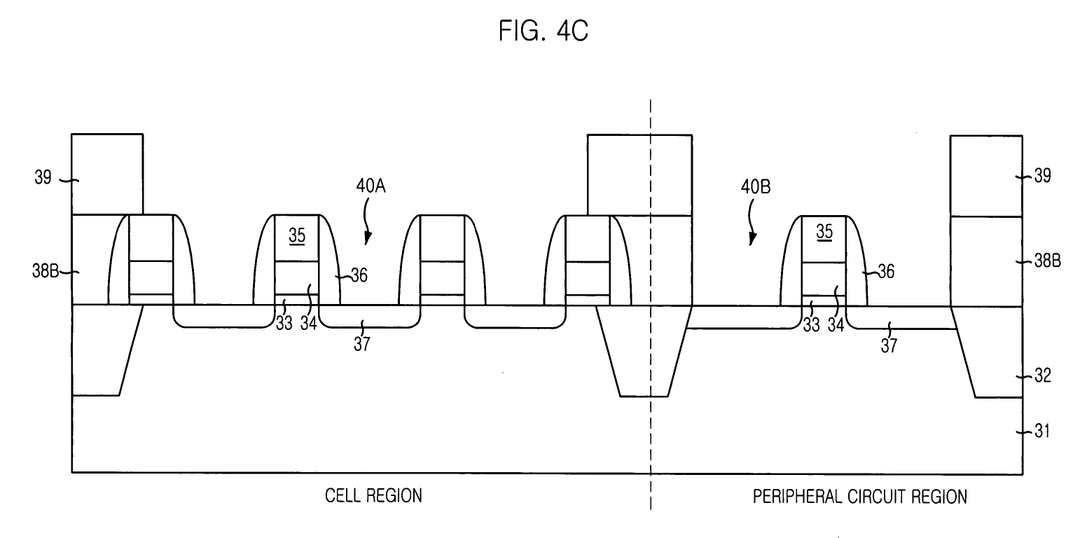

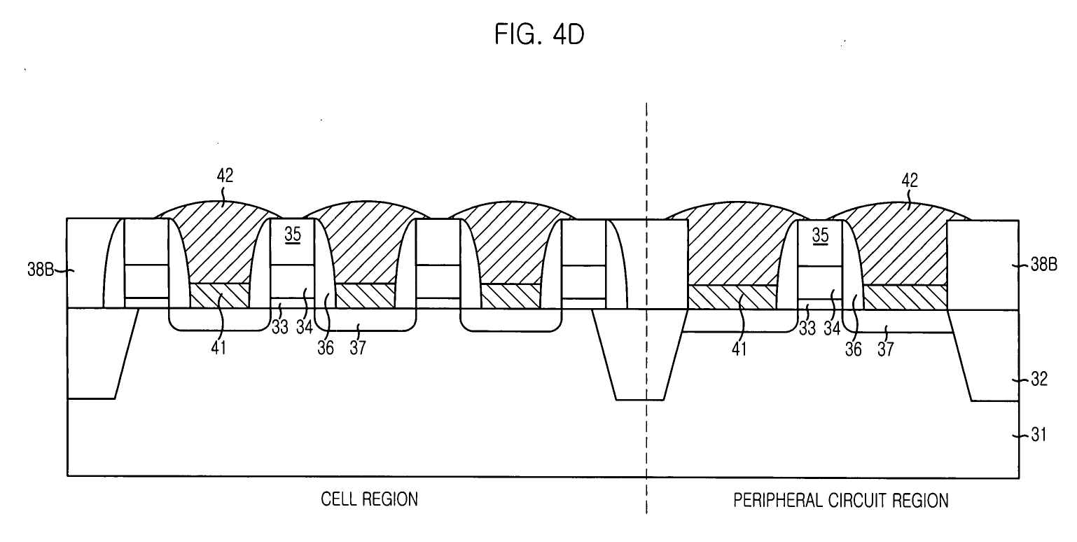

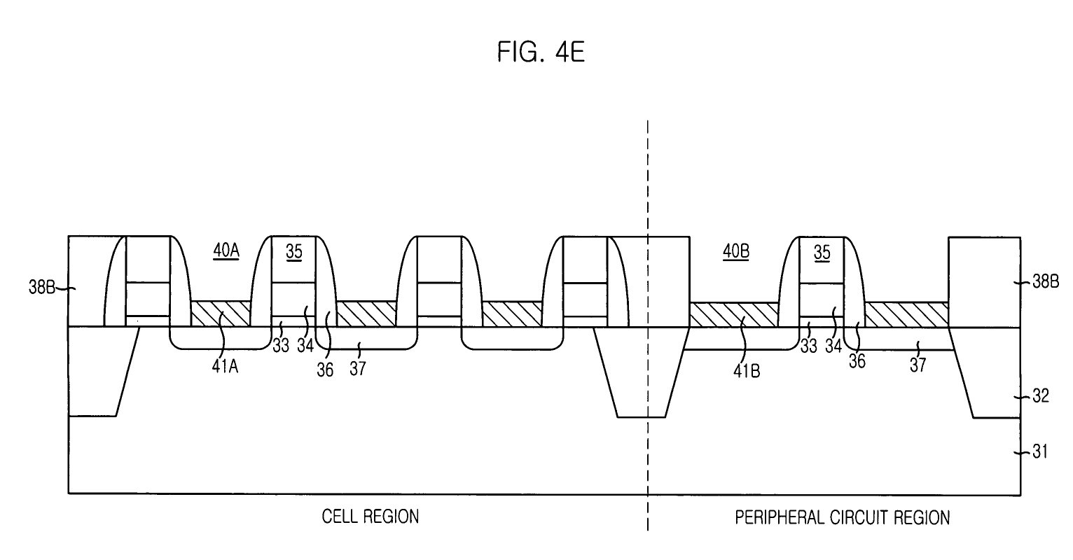

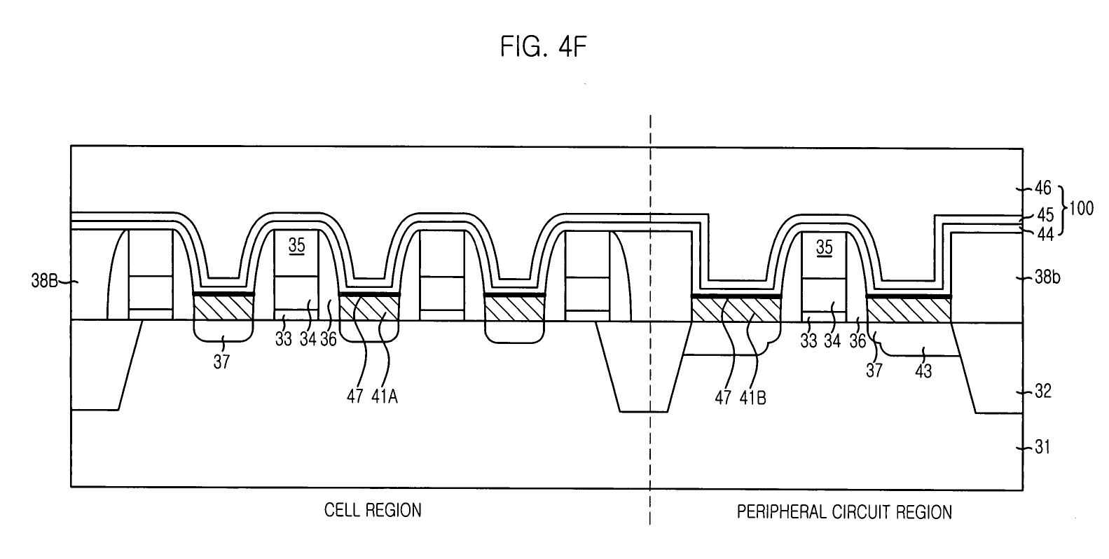

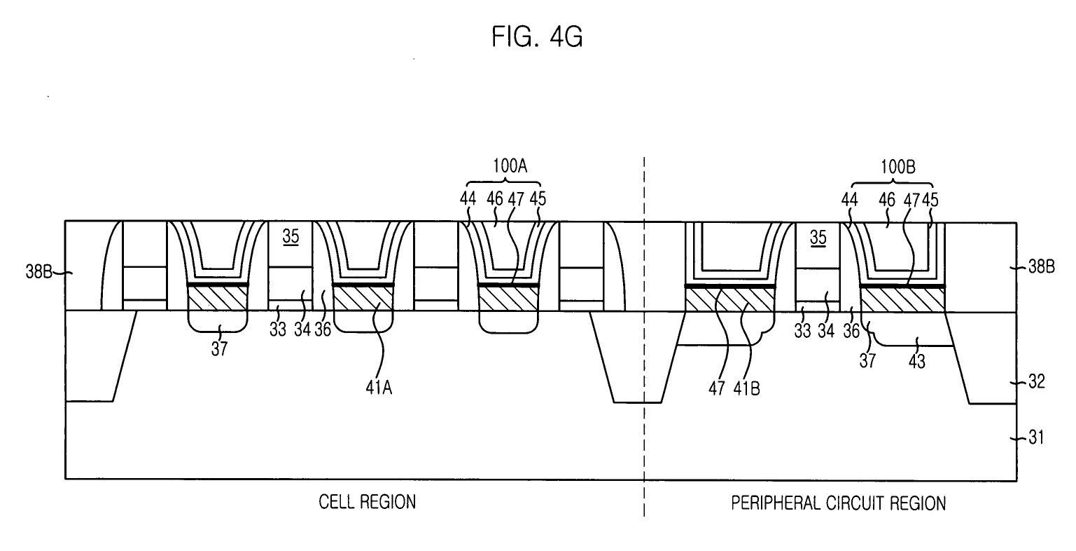

FIGS. 4A to 4G are cross-sectional views illustrating a method for fabricating a semiconductor device in accordance with the present invention.

As shown in FIG. 4A, an isolation process for isolating devices is employed on a substrate 31 defined with a cell region and a peripheral circuit region, thereby forming a device isolation layers 32. A plurality of gate patterns formed by sequentially stacking a gate insulation layer 33, a gate electrode 34, and a gate hard mask nitride layer 35 are formed on predetermined regions of the substrate 31. Herein, the device isolation layer 32 is formed through a shallow trench isolation (STI) process and the gate electrode 34 is selected from a group consisting of a polysilicon layer, a stack of the polysilicon layer and a tungsten layer, and a stack of the polysilicon layer and a tungsten silicide layer.

Subsequently, a spacer insulation layer is deposited on the substrate 31 including the gate patterns. Afterwards, a blanket-etch is employed, thereby forming a plurality of gate spacers 36 on sidewalls of the gate patterns. In one embodiment of the present invention, the gate hard mask nitride layer 35 and the gate spacers 36 use a material having an etch selectivity similar to that of a subsequent inter-layer insulation layer. However, in embodiments of the present invention where the inter-layer insulation layer comprises a silicon oxide layer, a silicon nitride layer is used as the gate hard mask nitride layer 35 and the gate spacers 36.

As described above, in some embodiments of the present invention, the processes for forming the gate patterns and the gate spacers 36 are simultaneously performed on the cell region and the peripheral circuit region.

Next, with use of a photoresist mask, a typical ion-implantation process is performed on the substrate 31 exposed between the gate patterns, thereby forming a plurality of lowly concentrated source/drain junction layers 37 serving a role of a source/drain of a transistor. Herein, the lowly concentrated source/drain junction layers 37 are referred to as a lightly doped drain (LDD) structure, wherein the LDD structure is independently formed in the cell region and the peripheral circuit region. The lowly concentrated source/drain junction layers 37 are formed by implanting ions such as N-type dopants such as arsenic (As) in an N-channel metal-oxide semiconductor field-effect transistor (NMOSFET). Also, in a P-channel metal-oxide semiconductor field-effect transistor (PMOSFET), the lowly concentrated source/drain junction layers 37 are formed by implanting ions such as P-type dopants such as boron (B). Hereinafter, for illustrative purposes, it is assumed that the exemplary transistor formed in the cell region and the peripheral circuit region is a NMOSFET.

Next, an inter-layer insulation layer 38 is formed on the substrate 31 including the gate patterns. The inter-layer insulation layer 38 uses an oxide material. More particularly, the inter-layer insulation layer 38 uses a silicon oxide-based material selected from a group consisting of borophosphosilicate glass (BPSG), undoped silicate glass (USG), tetraethylorthosilicate (TEOS), phosphosilicate glass (PSG), and borosilicate glass (BSG).

Next, the inter-layer insulation layer 38 is subjected to a first chemical mechanical polishing (CMP) process until the inter-layer insulation layer remains in a predetermined thickness on an upper portion of the gate hard mask nitride layer 35. According to one embodiment of the present invention, a thickness of the inter-layer insulation layer 38A remaining on the gate hard mask nitride layer 35 ranges from approximately 500 Å to approximately 1,500 Å.

The above mentioned first CMP process is performed by using a basic slurry with a pH level ranging form approximately 9 to approximately 12 along with using silica fabricated through a fumed or colloidal method as a polishing particle.

As shown in FIG. 4B, the inter-layer insulation layer 38A is subjected to a second CMP Process until a surface of the gate hard mask nitride layer 35 is exposed. In one embodiment of the present invention, the second CMP process is employed under a condition that a polishing process is stopped on the gate hard mask nitride layer 35.

During performing the second CMP process, a high selectivity slurry (HSS) having a high etch selectivity with respect to that of the gate hard mask nitride layer 35 is used for the slurry. The HSS may comprise a polishing selectivity of approximately 1 part of the gate hard mask nitride layer 35 to approximately 30 parts to approximately 100 parts of the oxide-based inter-layer insulation layer 38A.

In one embodiment of the present invention, the above described HSS has a pH level ranging from approximately 6 to approximately 8, so that the HSS is neutral. A polishing particle included in the slurry uses a cerium oxide (CeO₂)-based polishing particle.

In some embodiments of the present invention, the above described HSS helps the CMP process not be performed to a nitride layer, but sufficiently performed only to an oxide layer. Accordingly, a polishing is sufficiently performed to the inter-layer insulation layer 38A mainly made of the oxide layer. The polishing may stop at the nitride-based gate hard mask nitride layer 35.

Thus, the second CMP process using the HSS minimizes a damage on the gate hard mask nitride layer 35 and completely removes the inter-layer insulation layer 38A on the gate hard mask nitride layer 35.

In one embodiment of the present invention, after the second CMP process is completed, a planarized inter-layer insulation layer 38B remains between the gate patterns, and the inter-layer insulation layer 38B does not remain on the upper portions of the gate patterns.

In some embodiments of the present invention, if the first and the second CMP processes are performed as a series of the above described processes, a thickness of the gate hard mask nitride layer 35 can be uniformly maintained throughout an entire region of a wafer. Also, for forming a subsequent contact hole, a self aligned contact (SAC) etch uniformity can be improved through the first and the second CMP processes. The improvement of the SAC etch uniformity also improves an uniformity in the thickness of the gate hard mask nitride layer 35 during an isolation process for forming a subsequent landing plug and prevents a SAC fail.

As shown in FIG. 4C, a photoresist layer is deposited on an entire surface including the planarized inter-layer insulation layer 38B and the gate hard mask nitride layer 35 of which the surface is exposed, thereby forming a plurality of contact masks 39 by patterning the photoresist layer through photo-exposure and developing processes.

During forming the plurality of contact masks 39, since the first and the second CMP process are performed to the inter-layer insulation layer 38B until the surface of the gate hard mask nitride layer 35 is exposed, the uniformity in the thickness of the inter-layer insulation layer 38B remaining throughout the entire region of the wafer is secured, wherein it is possible to widely secure a process margin during patterning the contact masks 39.

In one embodiment of the present invention, the contact masks 39 are contact masks for forming a landing plug contact (LPC) in the cell region and thus, the contact masks 39 are not formed in the peripheral circuit region in accordance with the conventional semiconductor device structure. However, in accordance some embodiments of the present invention, the contact masks 39 are simultaneously formed in both the cell region and the peripheral circuit region.

Next, the inter-layer insulation layer 38B is etched by using the contact masks 39 as etch barriers, thereby performing a SAC process opening a plurality of contact holes 40A for forming the LPC in the cell region. In the peripheral circuit region, the inter-layer insulation layer 38B is also etched, thereby forming a plurality of holes 40B for forming an ESD. Hereinafter, the holes 40B are referred to as ESD holes.

In one embodiment of the present invention, since the inter-layer insulation layer 38B only remaining between the gate patterns is etched during performing the SAC etching process for forming the contact holes 40A and the ESD holes 40B, it is possible to minimize an etch damage on the gate hard mask nitride layer 35.

As shown in FIG. 4D, the contact masks 39 are removed and a pre-treatment cleaning process performed before forming a contact material. Etch residues (not shown) remain on sidewalls and bottom portions of the contact holes 40A and the ESD holes 40B formed by etching the inter-layer insulation layer 38B, and a silicon lattice defect is generated on surfaces of the lowly concentrated source/drain junction layers 37 due to the etching process. Furthermore, a native oxide layer is formed on the surfaces of the lowly concentrated source/drain junction layers 37 exposed as the contact holes 40A and the ESD holes 40B are formed. The etch residues and the silicon lattice defect degrades a leakage current property of a device and the native oxide layer increases a contact resistance, thereby deteriorating an electrical property of a device.

According to an embodiment of the present invention, a dry cleaning process or a wet cleaning process is performed before forming the contact material, and the pre-treatment cleaning process is performed after forming the contact holes 40A and the ESD holes 40B. The wet cleaning process applies a hydrogen fluoride (HF)-last cleaning process and the dry cleaning process applies a plasma cleaning process or a rapid thermal bake process. The wet cleaning process and the dry cleaning process are performed at a temperature ranging from approximately 25° C. to approximately 400° C. and at a temperature ranging from approximately 700° C. to approximately 900° C., respectively.

In one embodiment of the present invention, the HF-last cleaning process is a HF-based cleaning process which is performed last. For example, the HF-last cleaning process uses a chemical solution selected from a group consisting of RNO[(H₂SO₄+H₂O₂)→(NH₄OH+H₂O₂)→(HF-based BOE)], RNF[(H₂SO₄+H₂O₂)→(NH₄OH+H₂O₂)→HF], RO[(H₂SO₄+H₂O₂)→(HF-based BOE)], NO[(NH₄OH+H₂O₂)→(HF-based BOE)] and RF[(NH4OH+H2O2)→HF]. Herein, R(H₂SO₄+H₂O₂) is referred to as SPM. A denotation ‘→’ indicates a sequential order.

A gas used during performing the plasma cleaning process is selected from a group consisting of a hydrogen (H₂) gas, a mixed gas of H₂, and nitrogen (N₂). For instance, H₂, H₂/N₂, nitrogen trifluoride (NF₃), ammonia (NH₃), or tetrafluoromethane (CF₄) is used as an atmospheric gas. The plasma cleaning process is performed at a temperature ranging from approximately 25° C. to approximately 400° C.

In accordance with an embodiment of the present invention, the drying cleaning process of the pre-treatment cleaning process can use the rapid thermal bake process using a H₂-based gas. If the rapid thermal bake process is performed at a high temperature ranging from approximately 700° C. to approximately 900° C. in the H₂ gas and an H₂-based gas, there are effects of removing the etch residues and the thin native oxide layer simultaneously.

In one embodiment of the present invention, the above described pre-treatment cleaning process is performed without any time delays to maintain a clean surface around exposed portions of the contact holes 40A and the ESD holes 40B.

Next, a SPE process is performed after the pre-treatment cleaning process is completed and thus, a plurality of amorphous silicon layers 42 are grown inside of the contact holes 40A and the ESD holes 40B.

Herein, the SPE process thinly grows a plurality of epitaxial silicon layers 41 on the surfaces of the lowly concentrated source/drain junction layers 37 beneath the contact holes 40A/the ESD holes 40B even in an early deposition state and grows a plurality of amorphous silicon layers 42 thereon. During the deposition state, the SPE process is performed in an H₂ gas atmosphere at a temperature ranging from approximately 400° C. to approximately 700° C., along with supplying a mixed gas of silane (SiH₄) and phosphine (PH₃). As described above, during the deposition state, a doping concentration of P within the epitaxial silicon layers 41 and the amorphous silicon layers 42 is maintained at a low level ranging from approximately 1.0×10¹⁸ atoms/cm³ to approximately 1.0×10²¹ atoms/cm³. Furthermore, arsenic (As) is also used as an impurity doped within the epitaxial silicon layers 41 and the amorphous silicon layers 42. In addition, arsine (AsH₃) is flowed during growing the epitaxial layers 41 and the amorphous silicon layers 42.

A method for depositing the epitaxial silicon layers 41 and the amorphous silicon layers 42 through the SPE process is selected from a group consisting of a low pressure chemical vapor deposition (LPCVD) method, a very low pressure chemical vapor deposition (VLPCVD) method, a plasma enhanced chemical vapor deposition (PECVD) method, an ultra high vacuum chemical vapor deposition (UHCVD) method, a rapid thermal chemical vapor deposition (RTCVD) method, an atmosphere pressure chemical vapor deposition (APCVD) method, and a molecular beam epitaxy (MBE) method.

It should be appreciated that the epitaxial silicon layers 41 are grown during the early deposition state because the epitaxial silicon layers 41 are loaded to an amorphous silicon deposition apparatus without any time delays after a surface cleaning process is performed. During a pre-treatment surface cleaning process, if the cleaning process is performed by using a SPM solution obtained by mixing approximately 1 part of sulfuric acid (H₂SO₄) and approximately 20 parts of hydrogen peroxide (H₂O₂) at a temperature of approximately 90° C., and a buffered oxide etchant (BOE) solution obtained by mixing approximately 300 parts of ammonium fluoride (NF₄H) and approximately 1 part of HF, a surface of a silicon substrate becomes a state which a silicon dangling bond on the surface of the silicon substrate is combined with hydrogen, and thus a growth of the native oxide layer is prevented from growing for a predetermined period. Accordingly, since the native oxide layer is prevented from growing, the epitaxial silicon layers 41 are grown during the early deposition state of silicon. Furthermore, in accordance with an embodiment of the present invention, it should be appreciated that the epitaxial silicon layers 41 are grown during the early deposition state because a gas atmosphere used to deposit the amorphous silicon layers 42 comprises an H₂ gas. More specifically, as the H₂ gas is used, the gas atmosphere during performing the SPE process does not comprise an oxidation atmosphere but rather a reduction atmosphere. Therefore, the epitaxial silicon layers 41 can be grown even in the early deposition state of the amorphous silicon layers 42.

In one embodiment of the present invention, the contact material formed by using the SPE process can be formed by using germanium or silicon germanium in addition to silicon. Amorphous germanium or amorphous silicon germanium can be used to form the contact material.

As shown in FIG. 4E, the amorphous silicon layers 42 are selectively removed, wherein the epitaxial silicon layers 41 remain inside the contact holes 40A and the ESD holes 40B in a thickness ranging from approximately 400 Å to approximately 1,000 Å.

In accordance with an embodiment of the present invention, the amorphous silicon layers 42 are removed through either a dry etching process or a wet etching process. During performing the dry etching process, a mixed gas of hydrogen bromide (HBr) and chlorine (Cl₂) is used. During performing the wet etching process, an ammonium hydroxide (NH₄OH) solution is used.

In accordance with an embodiment of the present invention, the epitaxial silicon layers 41A remaining in the cell region after the amorphous silicon layers 42 are removed are referred to as the first contact layers 41A. The epitaxial silicon layers 41 remaining in the peripheral circuit region are referred to as the first ESD layers 41B.

As a result, the first contact layers 41A remain in form, wherein the first contact layers 41A partially fill the contact holes 40A in the cell region. The first ESD layers 41B remain in form, wherein the first ESD layers 41B partially fill the ESD holes 40B in the peripheral circuit region.

Afterwards, before a subsequent metal layer is deposited, a surface cleaning process is performed to remove the native oxide layer on surfaces of the first contact layers 41A and the first ESD layers 41B. The surface cleaning process is employed through a drying cleaning process or a wet cleaning process in a similar manner to the pre-treatment cleaning process performed after forming the contact holes 40A. The wet cleaning process uses a HF-last cleaning process, and the dry cleaning process uses either a plasma cleaning process or a rapid thermal bake process. In accordance with an embodiment of the present invention, the wet cleaning process and the dry cleaning process are performed at a temperature ranging from approximately 25° C. to approximately 400° C. and at a temperature ranging from approximately 700° C. to approximately 900° C., respectively.

In FIG. 4F, an ion-implantation mask (not shown) covering the cell region in a state that only the first contact layers 41A and the first ESD layers 41B remain is formed, and an ion-implantation process is performed in the peripheral circuit region, thereby forming a highly concentration source/drain junction layer 43.

Next, a metal layer 100 is deposited on the first contact layers 41A and the first ESD layers 41B until the contact holes 40A and the ESD holes 40B are completely filled.

According to one embodiment of the present invention, the metal layer 100 is formed through a CVD method or a physical vapor deposition (PVD) method. The metal layer 100 can be deposited in a single metal layer or dual metal layers by using each different metal layer. For example, the metal layer 100 can be formed by using a metal selected from a group consisting of Ti, Co, and Ni. In one embodiment of the present invention, after the formation of Ti, Co, or Ni, a TiN layer or a WN layer is formed as a barrier metal layer. Afterwards, W can be deposited thereon.

In accordance with an embodiment of the present invention, it is assumed that the metal layer 100 is formed by sequentially stacking a first metal layer 44 formed by selecting one metal of the group Ti, Co, and Ni, the barrier metal layer 45 is formed by using the TiN layer or the WN layer, and a second metal layer 46 is formed by using W.

In one embodiment of the present invention, if the contact is formed by using only the metal layer 100 in the perspective of the contact resistance, problems may arise such as contamination and deep level impurities generated when the metal layer 100 is directly in contact with the lowly concentration source/drain junction layer 37 or the highly concentration source/drain junction layer 43. Thus, to resolve the problems, the epitaxial silicon layer, i.e., the first contact layers 41A, with a predetermined thickness is reacted with the metal layer 100, thereby forming a plurality of silicide layers 47. For example, the first metal layer 44 may be formed as the metal layer 100, wherein a subsequent thermal process is performed, and the first contact layers 41A remain inside the contact holes 40A. The ESD holes 40B are reacted with the epitaxial silicon layer (i.e., the first ESD holes 41B), thereby forming the metal silicide layers 47. Afterwards, each of the metal silicide layers 47 is formed between each of the first contact layers 41A/the first ESD layers 41B and the metal contact layer 100. In accordance with an embodiment of the present invention, it is assumed that the metal layer 100 includes the metal silicide layers 47.

As shown in FIG. 4G, the metal layer 100 is subjected to a CMP process until the surfaces of the gate hard mask nitride layers 35 are exposed. Afterwards, a plurality of contact layers 100A and the plurality of second ESD layers 100B formed with the metal layer 100 completely filling the contact holes 40A and the ESD holes 40B are formed on the first contact layers 41A and the first ESD layers 41B. Through the CMP process, the second contact layers 100A formed on the first contact layers 41A are formed in the cell region and the second ESD layers 10B formed on the first ESD layers 41B are simultaneously formed in the peripheral circuit region.

In accordance with an embodiment of the present invention, the contact formed in the cell region is formed in a dual structure of the first contact layers 41A and the second contact layers 100A. In the peripheral circuit region, the ESD is formed in the identical structure with the cell contact, i.e., a dual structure of the first ESD layers 41B and the second ESD layers 100B.

Accordingly, the contact in the cell region becomes a stack structure by using the first contact layers 41A that are the epitaxial silicon layers and the second contact layers 100A that are the metal layers. The ESD in the peripheral circuit region has a stack structure of the first ESD layers 41B that comprise epitaxial silicon layers and has a stack structure of the second ESD layers 100B that comprises metal layers. In one embodiment of the present invention, the contact in the cell region has a stack structure of the first contact layers 41A comprising epitaxial silicon layers and has a stack structure of the second contact layers 100A formed by sequentially stacking the first metal layer 44, the barrier metal layer 45, and the second metal layer 46. The ESD in the peripheral circuit region has a stack structure of the first ESD layers 41B comprising epitaxial silicon layers and has a stack structure of the second ESD layers 100B formed by sequentially stacking the first metal layers 44, the barrier metal layers 45, and the second metal layers 46. It should be appreciated that in the cell region and the peripheral circuit region, the metal silicide layers 47 are formed between the epitaxial silicon layer and the first metal layer 44 after a post-annealing process.

As described above, in accordance with an embodiment of the present invention, as the contact in the cell region is formed in the dual structure (i.e., the dual structure by forming the metal silicide layers 47 between the first contact layers 41A made of epitaxial silicon layers and the second contact layers 100A made of the metal layer), it is possible to overcome a limitation on the contact resistance due to the formation of the contact with only the epitaxial silicon layer, thereby reducing the contact resistance. In accordance with an embodiment of the present invention, the second contact layers 100A comprising the metal layer, along with the second ESD layers 100B are used to provide an advantage in the perspective of the contact resistance, wherein the resistivity of the metal layer itself is approximately 100-times lower than that of the silicon layer.

Through the SPE process, the epitaxial silicon layers 41 and the amorphous silicon layers 42 are grown and then, the amorphous silicon layers 42 are selectively removed. Thus, it is not necessary to perform a thermal process for re-growth of the epitaxial silicon, thereby not only obtaining a process simplification but also reducing a thermal budget.

In accordance with an embodiment of the present invention, a subsequent thermal process for a re-growth of the SPE process is omitted or performed after a CMP process, thereby reducing a contact resistance of a semiconductor device but also improving reliability and yields of products.

The present patent application contains subject matter related to the Korean patent application No. KR 2005-0034106, filed in the Korean Patent Office on Apr. 25, 2005, the entire contents of which being incorporated herein by reference.

While the present invention has been described with respect to certain embodiments, it will be apparent to those skilled in the art that various changes and modifications may be made without departing from the spirit and scope of the invention as defined in the following claims.

1. A semiconductor device comprising:
an epitaxial layer formed using a solid phase epitaxy (SPE) process;
a first metal layer formed over the epitaxial layer;
a barrier metal layer formed over the first metal layer;
a second metal layer formed over the barrier metal layer; and
a metal silicide layer formed between the epitaxial layer and the first metal layer.

2. The semiconductor device of claim 1, wherein the epitaxial layer is one selected from a group consisting of an epitaxial silicon layer, an epitaxial germanium layer, and an epitaxial silicon germanium layer, wherein the metal silicide is formed after a post-annealing process, wherein the barrier metal is a nitride-based material.

3. The semiconductor device of claim 1, wherein the epitaxial layer is doped with impurities ranging from approximately 1.0×10¹⁸ atoms/cm³ to approximately 1.0×10²¹ atoms/cm³.

4. The semiconductor device of claim 3, wherein the impurities are one of phosphorus (P) and arsenic (As).

5. The semiconductor device of claim 1, wherein the first metal layer is one selected from a group consisting of titanium (Ti), cobalt (Co), and nickel (Ni), wherein the metal silicide is formed after a post-annealing process.

6. The semiconductor device of claim 1, wherein the barrier metal layer is one of a titanium nitride layer and a tungsten nitride layer.

7. The semiconductor device of claim 1, wherein the second metal layer includes tungsten (W).

8. The semiconductor device of claim 1, wherein the metal silicide layer is one selected from a group consisting of titanium silicide (TiSi₂), cobalt silicide (CoSi₂), and nickel silicide (NiSi₂).

9. The semiconductor device of claim 1, wherein the metal silicide layer is formed after a post-annealing process.

10. The semiconductor device of claim 1, wherein the barrier metal is a nitride-based material.

11. A semiconductor device comprising:
a substrate comprising a cell region and a peripheral circuit region;
a contact formed by stacking a first contact layer comprising an epitaxial layer and a second contact layer comprising a metal material on the cell region; and
an elevated source/drain (ESD) formed by stacking a first ESD layer comprising an epitaxial layer and a second ESD layer comprising a metal material on the peripheral circuit region of the substrate.

12. The semiconductor device of claim 11, wherein the first contact layer and the first ESD layer comprise the same epitaxial layer, and the second layer and the second ESD layer comprise the same metal layer.

13. The semiconductor device of claim 11, wherein the first contact layer and the first ESD layer are one selected from a group consisting of epitaxial silicon, epitaxial germanium, and epitaxial silicon germanium, wherein the first contact layer and the first ESD layer are formed through a SPE process.

14. The semiconductor device of claim 13, wherein the first contact layer and the first ESD layer are doped with impurities ranging from approximately 1.0×10¹⁸ atoms/cm³ to approximately 1.0×10²¹ atoms/cm³.

15. The semiconductor device of claim 14, wherein the impurities are one of phosphorus (P) and arsenic (As).

16. The semiconductor device of claim 11, wherein the second contact layer and the second ESD layer each includes:
a first metal layer formed over the first contact layer and the first ESD layer;
a barrier metal layer formed over the first metal layer;
a second metal layer formed over the barrier metal layer; and
a metal silicide layer formed between the first contact layer and the first metal layer, and between the first ESD layer and the first metal layer.

17. The semiconductor device of claim 16, wherein the first metal layer is one selected from a group consisting of Ti, Co, and Ni, wherein the barrier metal includes a nitride-based material.

18. The semiconductor device of claim 16, wherein the barrier metal layer is one selected from a group consisting of a titanium nitride layer and a tungsten nitride layer.

19. The semiconductor device of claim 16, wherein the second metal layer includes tungsten (W).

20. The semiconductor device of claim 16, wherein the metal silicide layer is one selected from a group consisting of TiSi₂, CoSi₂, and NiSi₂.

21-42. (canceled)

43. A method for fabricating a semiconductor device, the method comprising:
forming a substrate comprising a cell region and a peripheral circuit region, wherein a contact hole is formed over the cell region and an elevated source/drain (ESD) hole is formed over the peripheral circuit region;
forming an epitaxial layer filling partial portions of the contact hole and the ESD hole by using a solid phase epitaxy (SPE) process;
forming a first contact layer and a first ESD layer over the epitaxial layer, wherein the first contact layer and the first ESD layer are formed as an amorphous layer to fill the remaining portions of the contact hole and the ESD hole;
selectively removing the amorphous layer from the first contact layer and the first ESD layer; and
forming a second contact layer and a second ESD layer, the second contact layer and the second ESD layer comprising a metal contact layer, wherein the second contact layer and the second ESD layer fill the contact hole and the ESD hole, and the first contact layer and the first ESD layer comprising the epitaxial layer remain after removing the amorphous layer.

44. The method of claim 21, wherein the step of selectively removing the amorphous layer involves a dry etching process.

45. The method of claim 22, wherein the dry etching process uses a mixed gas of hydrogen bromide (HBr) and chlorine (Cl₂).

46. The method of claim 21, wherein the step of selectively removing the amorphous layer involves a wet etching process.

47. The method of claim 24, wherein the wet etching process uses an ammonium hydroxide (NH₄OH) solution.

48. The method of claim 21, wherein the first contact layer and the first ESD layer comprising the epitaxial layer is formed by using one selected from a group consisting of epitaxial silicon, epitaxial germanium, and epitaxial silicon germanium.

49. The method of claim 26, wherein the epitaxial layer is doped with impurities ranging from approximately 1.0×10¹⁸ atoms/cm³ to approximately 1.0×10²¹ atoms/cm³.

50. The method of claim 27, wherein the impurities are one of phosphorus (P) and arsenic (As).

51. The method of claim 21, wherein the steps of forming the second contact layer and the second ESD layer further comprise:
forming a first metal layer over the epitaxial layer;
forming a barrier metal layer which is nitride-based over the first metal layer; and
forming a second metal layer over the barrier metal layer.

52. The method of claim 29, wherein the first metal layer is one selected from a group consisting of Ti, Co, and Ni.

53. The method of claim 29, wherein the barrier metal layer is one selected from a group consisting to a titanium nitride layer and a tungsten nitride layer.

54. The method of claim 29, wherein the second metal layer comprises tungsten (W).

55. The method of claim 29, further comprising the step of forming a metal silicide layer, wherein the metal silicide layer is formed by inducing a reaction between the epitaxial layer and the first metal layer through a thermal process after performing the step of forming the first metal layer.

56. The method of claim 32, wherein the metal silicide layer is one selected from a group consisting of TiSi₂, CoSi₂, and NiSi₂.

57. The method of claim 21, wherein the step of forming the contact hole on the cell region of the substrate further comprises the step of performing a pre-treatment cleaning process with respect to the contact hole.

58. The method of claim 35, wherein the pre-treatment cleaning process is performed through one of a dry cleaning process and a wet cleaning process.

59. The method of claim 36, wherein the wet cleaning process uses a hydrogen fluoride (HF)-last cleaning process.

60. The method of claim 37, wherein the HF-last cleaning process uses a chemical solution selected from a group consisting of RNO[(H₂SO₄+H₂O₂)→(NH₄OH+H₂O₂) →(HF-based BOE)], RNF[(H₂SO₄+H₂O₂)→(NH₄OH+H₂O₂)→HF], RO[(H₂SO₄+H₂O₂)→(HF-based BOE)], NO[(NH₄OH+H₂O₂)→(HF-based BOE)] and RF[(NH₄OH+H₂O₂)→HF].

61. The method of claim 36, wherein the dry cleaning process is performed through a plasma cleaning process and thermal bake process.

62. The method of claim 39, wherein the plasma cleaning process uses an atmospheric gas selected from a group consisting of hydrogen (H₂), H₂/nitrogen (N₂), nitrogen trifluoride (NF₃), ammonia (NH₃), and tetrafluoromethane (CF₄).

63. The method of claim 35, wherein the wet cleaning process is performed at a temperature ranging from approximately 25° C. to approximately 400° C.

64. The method of claim 36, wherein the dry cleaning process involves a plasma process at a temperature ranging from approximately 25° C. to approximately 400° C. or a rapid thermal bake process at a temperature ranging from approximately 700° C. to approximately 900° C.
